(19) United States
(12) Patent Application Publication
(10) Pub. No.: US 2025/0267830 A1
(43) Pub. Date: Aug. 21, 2025

(54) INTEGRATED CONTROLLER FOR COOLING MODULE

(71) Applicant: COAVIS, Sejong-si (KR)

(72) Inventors: Kusung KWON, Daejeon (KR); Youngsub JANG, Sejong-si (KR)

(73) Assignee: COAVIS, Sejong-si (KR)

(21) Appl. No.: 19/055,648

(22) Filed: Feb. 18, 2025

(30) Foreign Application Priority Data
Feb. 19, 2024 (KR) 10-2024-0023475

(51) Int. Cl. H05K 9/00

(52) U.S. Cl. CPC H05K 9/0032; H05K 9/0064

(57) ABSTRACT

The present disclosure relates to an integrated controller for a cooling module, the integrated controller including: a case having a connector: a plurality of terminals coupled to the case and having one end protruding into the case and the other end protruding into the connector; a control board accommodated in the case and coupled and electrically connected to the one end of the plurality of terminals; and a shielding plate shielding electromagnetic waves by surrounding the plurality of terminals and coupled to the case, in which the plurality of terminals generating electromagnetic waves is surrounded by the shielding plate to be able to absorb the electromagnetic waves can be absorbed such that the integrated controller can protect surrounding electronic devices and systems.

### CROSS-REFERENCE TO RELATED APPLICATIONS

This application claims priority under 35 U.S.C. § 119 to Korean Patent Application No. 10-2024-0023475, filed on Feb. 19, 2024, in the Korean Intellectual Property Office, the disclosure of which is incorporated herein by reference in its entirety.

### TECHNICAL FIELD

The following disclosure relates to a structure that can shield electromagnetic waves generated by an integrated controller that controls a cooling module in which parts for pumping and circulating a coolant of a vehicle are integrally modularized.

### BACKGROUND

Electric vehicles are operated using a motor that is powered and driven by a battery or a fuel cell, so they produce a small amount of carbon emissions and generates less noise. Further, electric vehicles use motors with superior energy efficiency compared to conventional engines, so they are environmentally friendly.

Such electric vehicles are equipped with a heat management system for cooling/heating for conditioning the interior air and for cooling electric parts such as a driving motor, a battery, an inverter.

A heat management system is equipped with a coolant system for heating the interior of a vehicle and cooling and heating electric parts. Such as coolant system has a lot of parts for circulation of a coolant and a lot of long pipelines connecting the parts, so the process of assembling the coolant system is complicated and difficult. Accordingly, such a coolant system for a vehicle is simplified by configuring a reservoir tank, directional control valves, a coolant pump, an integrated controller, etc., into an integrated cooling module.

However, electromagnetic waves are generated when the integrated controller for the cooling module operates, so there is a problem that the electromagnetic waves generated by the integrated controller may adversely affect the surrounding electronic devices.

### RELATED ART DOCUMENT

### Patent Document

KR 10-2525194 B1 (registration date: 2023.04.19.) “Integrated device for water pump and valve”

### SUMMARY

An embodiment of the present disclosure is directed to providing an integrated controller for a cooling module that can protect surrounding electronic devices and systems by shielding electromagnetic waves that are generated.

In one general aspect, an integrated controller for a cooling module of the present disclosure includes: a case having a connector: a plurality of terminals coupled to the case and having one end protruding into the case and the other end protruding into the connector; a control board accommodated in the case and coupled and electrically connected to the one end of the plurality of terminals; and a shielding plate shielding electromagnetic waves by surrounding the plurality of terminals and coupled to the case.

The plurality of terminals may include a motor output unit terminal.

An end of the shielding plate may protrude into the case.

A connection tab extending upward may be formed on a side of the shielding plate and protrudes into the case, and the connection tab may be coupled and electrically connected to the control board.

A ground layer may be formed on the control board and the connection tab may be electrically connected with the ground layer.

Another end of the shielding plate may protrude into the connector.

Fixing tabs extending toward an open side of the connector may be formed on another side of the shielding plate and may protrude into the connector

The shielding plate may include: a bottom plate covering the lower side of the plurality of terminals; and a pair of first side plates covering both width-directional sides of the plurality of terminals and extending upward from the bottom plate.

The shielding plate may further include a second side plate covering a longitudinal-side of the plurality of terminals and extending upward from the bottom plate.

The plurality of terminals and the shielding plate may be integrally formed with the case by insert injection molding.

The plurality of terminals and the shielding plate may be integrally formed with fixing portions by insert injection molding, thereby forming a terminal-shielding plate assembly; and the terminal-shielding plate assembly may be integrally formed with the case by over molding.

### BRIEF DESCRIPTION OF THE DRAWINGS

FIGS. 1 to 4 are a perspective assembly view, an exploded perspective view, a partial perspective view, and a right side view illustrating an integrated controller for a cooling module according to an embodiment of the present disclosure.

FIGS. 5 to 7 are a plan cross-sectional view, a front cross-sectional view, and a side cross-sectional view illustrating the integrated controller for a cooling module according to an embodiment of the present disclosure; and

FIGS. 8 and 9 are perspective views illustrating terminals, fixing portions, and a shielding plate according to the present disclosure.

### DETAILED DESCRIPTION OF EMBODIMENTS

Hereafter, an integrated controller for a cooling module of the present disclosure is described in detail with reference to the accompanying drawings.

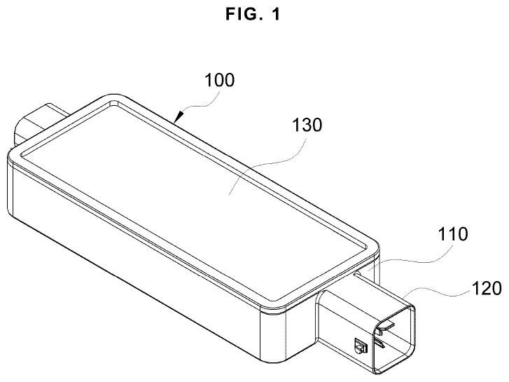

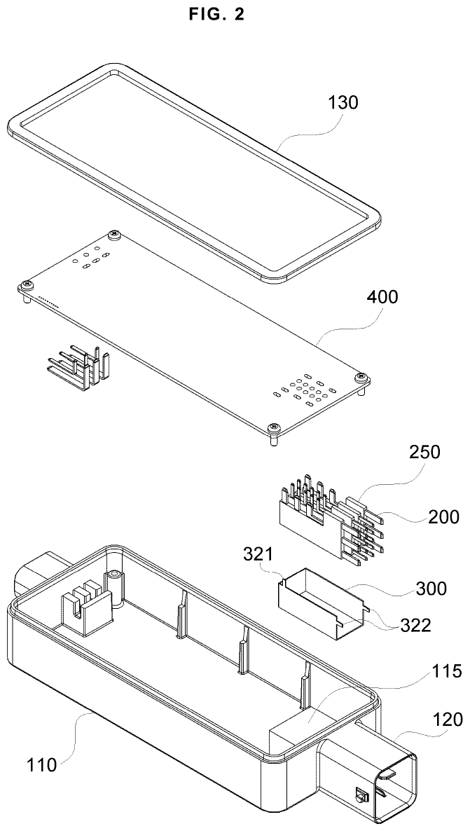

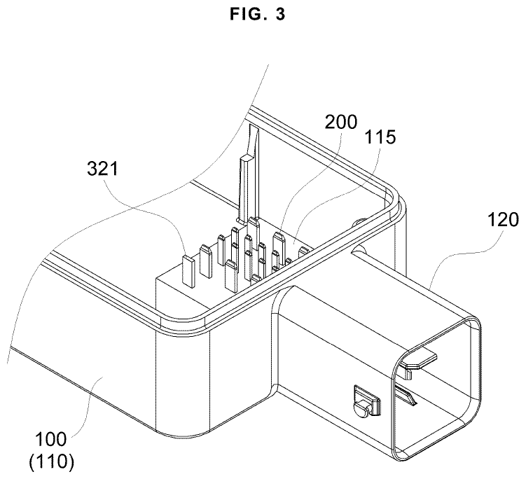

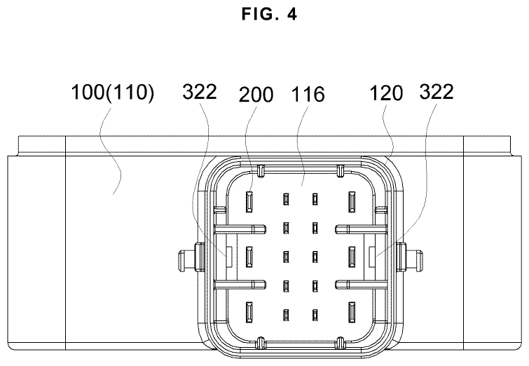

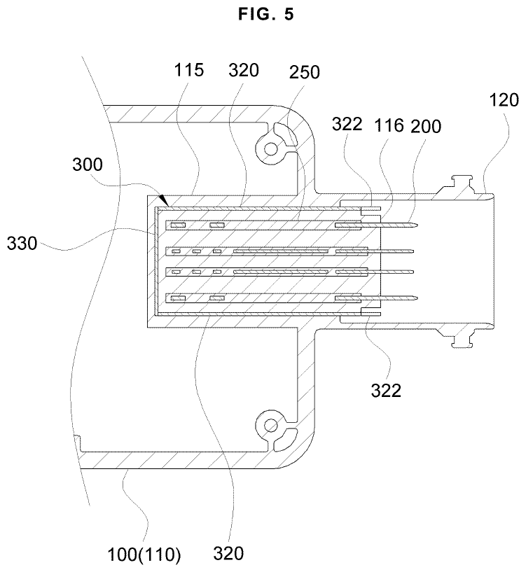

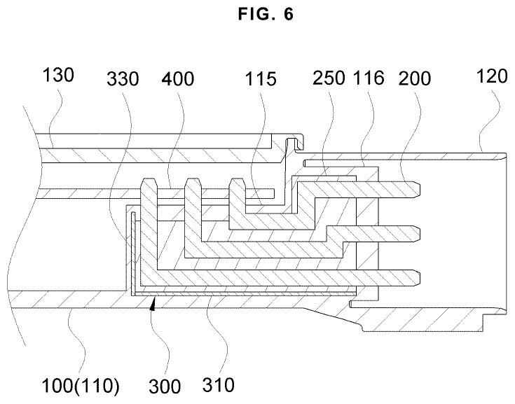

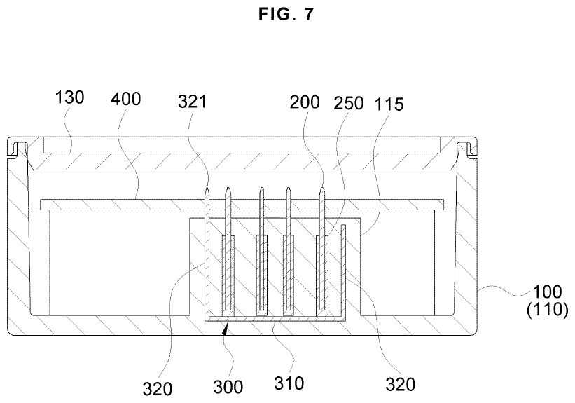

FIGS. 1 to 4 are a perspective assembly view, an exploded perspective view, a partial perspective view, and a right side view illustrating an integrated controller for a cooling module according to an embodiment of the present disclosure, and FIGS. 5 to 7 are a plan cross-sectional view, a front cross-sectional view, and a side cross-sectional view illustrating the integrated controller for a cooling module according to an embodiment of the present disclosure.

As illustrated in the drawings, an integrated controller for a cooling module according to an embodiment of the present disclosure may include a case 100, a plurality of terminals 200, a control board 400, and a shielding plate 300.

The case 100 may include a case body 110 having an empty interior and having a container shape with an open top, and a cover 130 covering the open top by being coupled to the upper side of the case body 110. Further, a connector 120 may protrude from the case body 110, and the case body 110 and the connector 120 may be integrally made of a plastic material through injection molding.

The plurality of terminals 200 may be made of a metal material and may be coupled and fixed to the case body 110. For example, the plurality of terminals 200 may be integrally formed with the case body 110 by insert injection molding. One end of the plurality of terminals 200 may protrude into the case body 110 and the other end thereof may protrude into the connector 120.

The control board 400 is accommodated in the case 110 and may be coupled and fixed to the case body 110. For example, the case body 110 may have an inner protrusion 115 formed inside the case body 110 at a position adjacent to the connector 120 and an outer protrusion 116 formed inside the connector 120. Further, the plurality of terminals 200 may be coupled and fixed to the inner protrusion 115 and the outer protrusion 116. The one end of the plurality of terminals 200 may protrude upward from the inner protrusion 115 and the other end may protrude toward another side in the longitudinal direction of the outer protrusion 116. Further, a plurality of holes in which the one end of the plurality of terminals 200 can be inserted and coupled may be formed at the control board 400. After the one end of the plurality of terminals 200 are inserted and coupled in the holes of the control board 400, the control board 400 and the plurality of terminals 200 can be coupled and electrically connected by soldering, etc.

The shielding plate 300 is disposed to surround the plurality of terminals 200 and serves to prevent electromagnetic waves from being discharged out of the case 100 by shielding the electromagnetic waves generated by the plurality of terminals 200. The shielding plate 300 may be coupled and fixed to the case body 110 and may be coupled and fixed to the inner protrusion 115 and the outer protrusion 116. For example, the shielding plate 300 may be integrally formed with the case body 110 by insert injection molding. The shielding plate 300 may be made of various materials in various shapes that can absorb electromagnetic waves.

Therefore, according to the integrated controller for a cooling module of the present disclosure, since the plurality of terminals that generate electromagnetic waves is surrounded with the shielding plate such that the electromagnetic waves are absorbed and discharged outside, it is possible to protect surrounding electronic devices and systems.

Further, the plurality of terminals 200 may include a motor output unit terminal that outputs power to a motor of a coolant pump. The control board 400 switches a current to control a current that is supplied to the motor of the coolant pump, whereby the variation of a current over time is large, so a lot of electromagnetic waves are generated. Accordingly, in the present disclosure, since the shielding plate 300 is disposed at the connector 120 in which the motor output unit terminal is disposed, it is possible to prevent electromagnetic waves from being discharged outside.

Further, the shielding plate 300 may include a bottom plate 310 and a pair of first side plates 320 and may further include a second side plate 330. The bottom plate 310 may be spaced apart under the plurality of terminals 200 in a height direction and the pair of first side plates 320 may be spaced apart at both sides of the plurality of terminals 200 in a width direction. That is, the shielding plate 300 may be formed in a shape in which the pair of first side plates 320 extends upward at both width-directional ends of the bottom plate 310. Further, the second side plate 330 may be spaced apart from a side of the plurality of terminals 200 in the longitudinal direction and may extend upward from a longitudinal end of the bottom plate 310. Accordingly, electromagnetic waves that are discharged to the height-directional lower side, width-direction both sides, and a longitudinal side of the plurality of terminals 200 can be effectively shielded by the shielding plate 300.

Further, an end of the shielding plate 300 may protrude into the case body 110. For example, the shielding plate 300 may have a connection tab 321 extending upward from the first side plate 320 and the connection tab 321 may protrude into the case body 110. Accordingly, in insert injection molding, the connection tab 321 of the shielding plate 300 is inserted and fixed in holes formed at a mold and then resin is injected, whereby the case body 110 and the shielding plate 300 can be easily integrally formed.

Further, a ground layer is formed on the control board 400 and the connection tab 321 of the shielding plate 300 can be coupled to the control board 400 and electrically connected to the ground layer. Accordingly, electromagnetic waves absorbed by the shielding plate 300 can be discharged outside through the ground layer. In this case, electromagnetic waves can be discharged outside by connecting a separate grounding wire to the ground layer of the control board 300 and the ground layer formed at a position corresponding to the upper side of the plurality of terminals 200 may serve to shield electromagnetic waves.

Further, another end of the shielding plate 300 may protrude into the connector 120. For example, the shielding plate 300 may have fixing tabs 322 extending from the pair of first side plates 320 toward the open side of the connector 120 in the longitudinal direction, and the fixing tabs 322 may protrude into the connector 120. Accordingly, in insert injection molding, the fixing tabs 322 of the shielding plate 300 are inserted and fixed in holes formed at a mold and then resin is injected, whereby the case body 110 and the shielding plate 300 can be easily integrally formed.

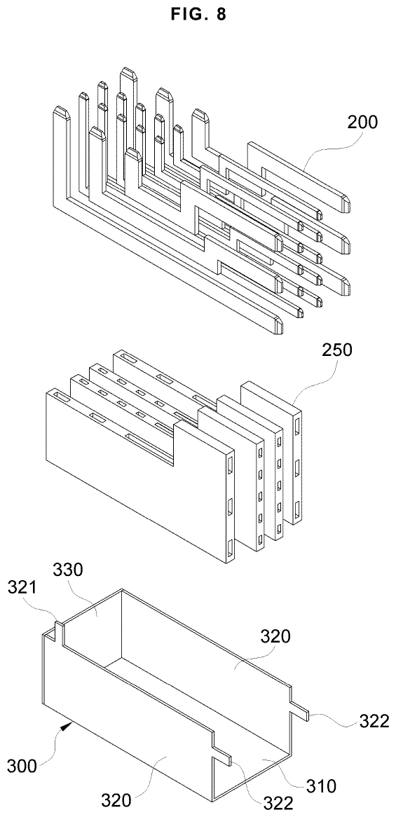

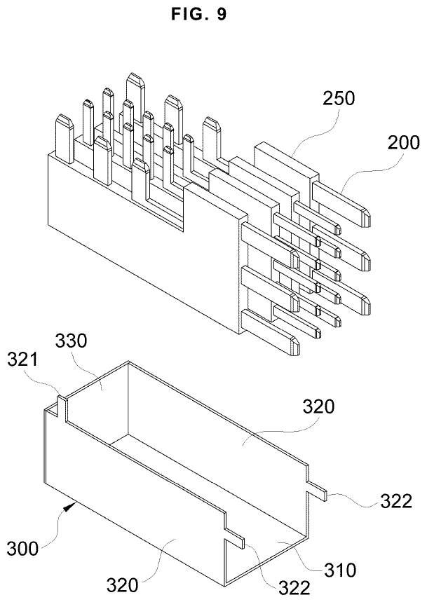

FIGS. 8 and 9 are perspective views illustrating terminals, fixing portions, and a shielding plate according to the present disclosure.

As illustrated in the drawings, the integrated controller for a cooling module according to an embodiment of the present disclosure may further include fixing portions 250 coupling the plurality of terminals 200. For example, some terminals of the plurality of terminals 200 are coupled to the fixing portions 250, respectively, whereby a plurality of sets of terminal groups can be formed. Further, for example, the plurality of terminals 200 may integrally formed with the fixing portions 25 by insert injection molding. Further, the plurality of sets of terminal groups may be integrally formed with the case by over molding together with the shielding plate 300. Accordingly, the plurality of terminals 200 and the shielding plate 300 can be accurately disposed and easily manufactured.

Further, though not illustrated, the plurality of terminals 200 and the shielding plate 300 are fixed in a mold and then insert injection molding is performed, whereby a terminal-shielding plate assembly in which the fixing portions, the plurality of terminals, and the shielding plate are integrally formed can be implemented. Thereafter, the terminal-shielding plate assembly can be integrally formed with the case by over molding.

According to the integrated controller for a cooling module of the present disclosure, since the part that generates electromagnetic waves is surrounded with the shielding plate such that the electromagnetic waves are absorbed and discharged outside, there is the advantage in that it is possible to protect electronic devices and systems disposed around the integrated controller.

The present disclosure is not limited to the embodiments described above, may be used for various fields, and may be modified in various ways by those skilled in the art without departing from the spirit of the present disclosure described in claims.

What is claimed is:

1. An integrated controller for a cooling module, the integrated controller comprising:
a case having a connector;
a plurality of terminals coupled to the case and having one end protruding into the case and the other end protruding into the connector;
a control board accommodated in the case and coupled and electrically connected to the one end of the plurality of terminals; and
a shielding plate shielding electromagnetic waves by surrounding the plurality of terminals and coupled to the case.

2. The integrated controller of claim 1, wherein the plurality of terminals includes a motor output unit terminal.

3. The integrated controller of claim 1, wherein an end of the shielding plate protrudes into the case.

4. The integrated controller of claim 3, wherein a connection tab extending upward is formed on a side of the shielding plate and protrudes into the case, and the connection tab is coupled and electrically connected to the control board.

5. The integrated controller of claim 4, wherein a ground layer is formed on the control board and the connection tab is electrically connected with the ground layer.

6. The integrated controller of claim 1, wherein another end of the shielding plate protrudes into the connector.

7. The integrated controller of claim 6, wherein fixing tabs extending toward an open side of the connector are formed on another side of the shielding plate and protrude into the connector.

8. The integrated controller of claim 1, wherein the shielding plate includes:
a bottom plate covering the lower side of the plurality of terminals; and
a pair of first side plates covering both width-directional sides of the plurality of terminals and extending upward from the bottom plate.

9. The integrated controller of claim 8, wherein the shielding plate further includes a second side plate covering a longitudinal-side of the plurality of terminals and extending upward from the bottom plate.

10. The integrated controller of claim 1, wherein the plurality of terminals and the shielding plate are integrally formed with the case by insert injection molding.

11. The integrated controller of claim 10, wherein the plurality of terminals and the shielding plate are integrally formed with fixing portions by insert injection molding, thereby forming a terminal-shielding plate assembly; and the terminal-shielding plate assembly is integrally formed with the case by over molding.
